(19) United States
(12) Patent Application Publication
(10) Pub. No.: US 2019/0123303 A1
(43) Pub. Date: Apr. 25, 2019

(54) DISPLAY DEVICE

(71) Applicant: Japan Display Inc., Tokyo (JP)

(72) Inventor: Koji YASUKAWA, Tokyo (JP)

(21) Appl. No.: 16/164,961

(22) Filed: Oct. 19, 2018

(30) Foreign Application Priority Data
Oct. 25, 2017 (JP) 2017-205843

(51) Int. Cl. H01L 51/52; H01L 27/32

(52) U.S. Cl. CPC H01L 51/5265; H01L 27/3211

(57) ABSTRACT

A display device includes a pixel includes a plurality of sub-pixels, a first cap layer having a first optical distance, and a second cap layer having a second optical distance different from the first optical distance. Each of the plurality of sub-pixels includes a first electrode, a second electrode facing the first electrode, and a light emitting layer between the first electrode and the second electrode. The first cap layer and the second cap layer are arranged in at least one of the plurality of subpixels and are arranged on the second electrode.

### CROSS REFERENCE TO RELATED APPLICATIONS

This application is based upon and claims the benefit of priority from the prior Japanese Patent Application No. 2017-205843, filed on Oct. 25, 2017, the entire contents of which are incorporated herein by reference.

### FIELD

One embodiment of the present invention is related to a display device. One embodiment of the invention disclosed by the present specification is related to a pixel structure of a display device.

### BACKGROUND

An organic EL (Electroluminescence) display device is an example of a display device. An organic EL display device has an organic light emitting element (called a “light emitting element” herein) in each of a plurality of sub-pixels formed on a substrate. A light emitting element includes a layer (called an “EL layer” herein) which has an organic compound between a pair of electrodes (cathode, anode) and is driven by supplying a current between the pair of electrodes.

Although there is a technique for improving efficiency by increasing optical interference by arranging a cap layer on a light extraction surface side of a cathode in an organic EL element with a top emission structure which uses a semi-reflective metal layer for the cathode and uses a total reflection metal layer under the anode or the cathode as a technique for improving the efficiency of an organic EL display device, it was difficult to achieve a design which simultaneously satisfies high efficiency and wide viewing angle characteristics. In addition, although there is a technique for achieving both high efficiency and wide viewing angle characteristics by changing a layer thickness of a hole transport layer by dividing a light emitting area of a light emitting element, or by changing a light emitting material to obtain different emission spectrums, a drive voltage is changed when the layer thickness of a hole transport layer is changed or a light emitting material is changed, it is difficult to make the divided sub-pixels emit light uniformly, and since the luminosity lifetime is different, there was a problem whereby the shape of the emission spectrum changes depending on the lighting time. Furthermore, an invention is disclosed in Japanese Laid Open Patent Application No. 2013-251226 as an invention for adjusting light emission luminosity in which two cap layers are stacked in each of a R, G, and B sub-pixel and light emission luminosity is adjusted by adjusting the layer thickness of one of the cap layers.

### SUMMARY

A display device related to one embodiment of the present invention includes a pixel includes a plurality of sub-pixels, a first cap layer having a first optical distance, and a second cap layer having a second optical distance different from the first optical distance. Each of the plurality of sub-pixels includes a first electrode, a second electrode facing the first electrode, and a light emitting layer between the first electrode and the second electrode. The first cap layer and the second cap layer are arranged in at least one of the plurality of subpixels and are arranged on the second electrode.

### BRIEF DESCRIPTION OF DRAWINGS

FIG. 1A is a schematic cross-sectional diagram of a display device according to one embodiment of the present invention;

FIG. 1B is a schematic cross-sectional diagram of a display device according to one embodiment of the present invention;

FIG. 2 is a schematic top surface diagram of a display device according to one embodiment of the present invention;

FIG. 3A is a schematic cross-sectional diagram of a display device according to one embodiment of the present invention;

FIG. 3B is a schematic cross-sectional diagram of a display device according to one embodiment of the present invention;

FIG. 3C is a schematic cross-sectional diagram of a display device according to an embodiment of the present invention;

FIG. 4 is a schematic top surface diagram of a display device according to one embodiment of the present invention;

FIG. 5 is a schematic top surface diagram of a display device according to one embodiment of the present invention;

FIG. 6 is a schematic top surface diagram of a display device according to one embodiment of the present invention;

FIG. 7A is a schematic top surface diagram for explaining a manufacturing method of a display device according to one embodiment of the present invention;

FIG. 7B is a schematic top surface diagram for explaining a manufacturing method of a display device according to one embodiment of the present invention; and

FIG. 7C is a schematic top surface diagram for explaining a manufacturing method of a display device according to one embodiment of the present invention.

### DESCRIPTION OF EMBODIMENTS

Each embodiment of the present invention is explained below while referring to the drawings. However, the present invention can be carried out in various modes within a scope that does not depart from the gist of the invention, and should not to be interpreted as being limited to the description contents of the embodiments exemplified herein.

Although the drawings may be schematically represented with respect to width, thickness, shape and the like of each part as compared with their actual form in order to make the explanation more clear, they are only an example and an interpretation of the present invention is not limited. In the present specification and each drawing, the same reference numerals are attached to elements having the same functions as those described with reference to preceding drawings, and overlapping explanations may be omitted.

In the present invention, in the case where a plurality of layers is formed by etching or irradiating one certain layer, the plurality of layers may have different functions and roles. However, the plurality of layers is derived from layers formed as the same layer and in the same process and includes the same layer structure and the same material. Therefore, the plurality of layers is defined as existing in the same layer.

In the present specification and the scope of the patent claims, when expressing a mode in which a structure is arranged above a certain structure, in the case of simply describing “over” or “on”, unless otherwise specified, these include both a case where a structure is arranged directly above so as to be in contact with another structure, and a case where a structure is arranged above a certain structure with another structure provided therebetween.

### 1. First Embodiment

### 1-1. Structure of a Pixel

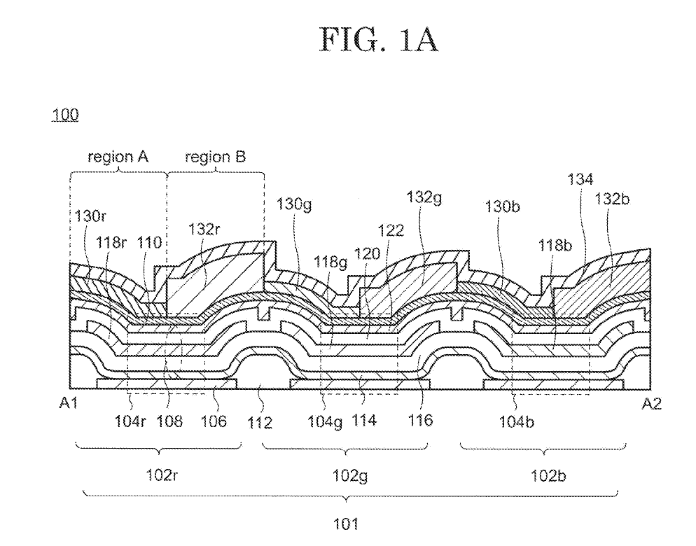

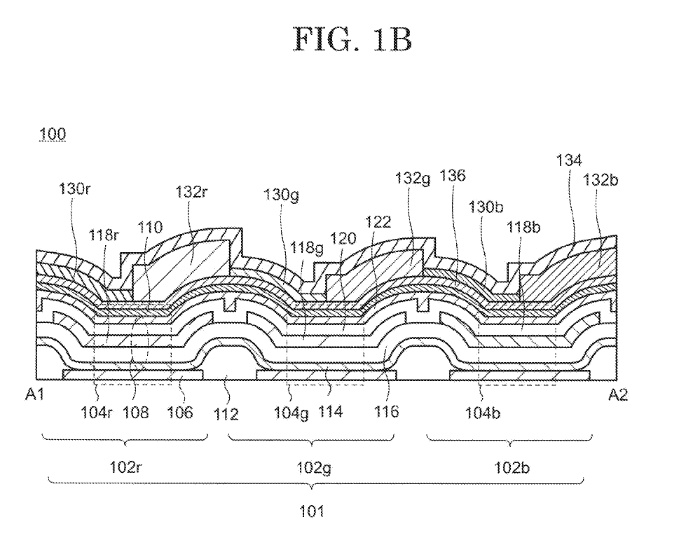

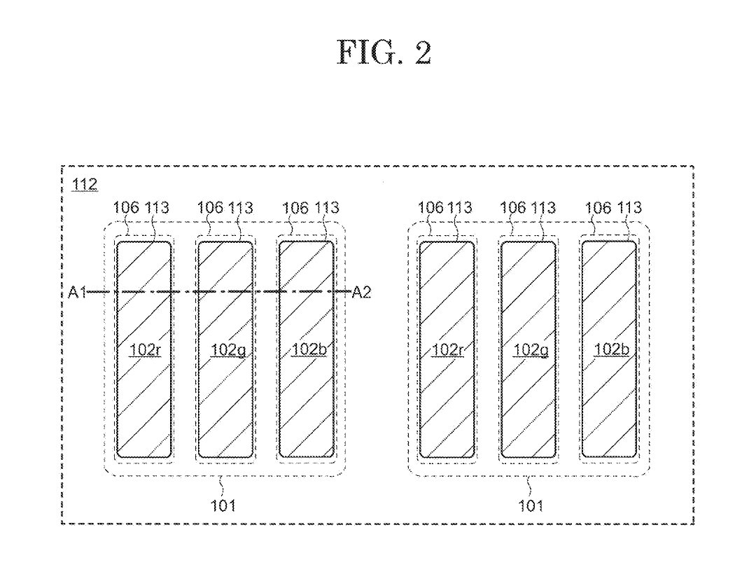

FIG. 1A and FIG. 2 are each a schematic cross-sectional diagram and a schematic top surface diagram of a display device 100 of the first embodiment. A cross-section along the dotted line A1-A2 in FIG. 2 corresponds to FIG. 1A. The display device 100 has a display region in which pixels 101 are arranged, and the pixel 101 includes a plurality of sub-pixels 102. A first sub-pixel 102b, a second sub-pixel 102g and a third sub-pixel 102r are shown in FIG. 2 as the sub-pixels included in the pixel 101. These sub-pixels 102 are arranged adjacently and correspond to different colors. The sub-pixels 102 corresponding to different colors form a pixel 101. For example, the pixel 101 can include three kinds of sub-pixels 102 which provide the three primary colors of red, green, and blue, and using this full color display can be performed. Although an explanation is given herein assuming that the first sub-pixel 102b, the second sub-pixel 102g and the third sub-pixel 102r provide blue, green, and red respectively, as long as a structure is adopted whereby different light emitting colors between two adjacent sub-pixels 102 is provided, the structure of the display device 100 is not limited to the structure described above. For example, the display device 100 can be formed so that the light emission wavelength obtained from the second sub-pixel 102g is longer than the light emission wavelength obtained from the first sub-pixel 102b and shorter than the light emission wavelength obtained from the third sub-pixel 102r. Here, the light emission wavelength corresponds to the light emission peak wavelength obtained from the sub-pixel 102, the light emission peak wavelength of the light emitting element 104 (described later) arranged in a sub-pixel 102, or the light emission peak wavelength of a light emitting material of the light emitting element 104.

In FIG. 2, an example is shown in which the area of each sub-pixels 102 are equivalent. However, the arrangement and size of the sub-pixels 102 are not limited, and the sizes and shapes of the first sub-pixel 102b, the second sub-pixel 102g, and the third sub-pixel 102r may be the same or different from each other. In addition, the arrangement of the sub-pixels 102 may be a stripe arrangement, a delta arrangement, a mosaic arrangement or a pentile arrangement.

As is shown in FIG. 1A, the first sub-pixel 102b, the second sub-pixel 102g and the third sub-pixel 102r are arranged with light emitting elements 104b, 104g and 104r respectively. Each of the light emitting elements 104b, 104g and 104r is formed by a first electrode 106, an EL layer 108 above the first electrode 106, and a second electrode 110 above the EL layer 108. The light emitting elements 104b, 104g and 104r are referred to herein as a first light emitting element, a second light emitting element and a third light emitting element respectively. Furthermore, in FIG. 1A, a substrate for supporting the sub-pixels 102 and various circuits for driving the sub-pixels 102 and the like are omitted.

The first electrode 106 is arranged for each sub-pixel 102 and is formed so that each is independently provided with a potential. On the other hand, the second electrode 110 is arranged across a plurality of sub-pixels 102 and is shared by the plurality of sub-pixels 102. The display device 100 is formed so that a constant potential is supplied to the second electrode 110.

One of the first electrode 106 and the second electrode 110 is formed so that visible light passes through and visible light is reflected by the other. In addition, one of the first electrode 106 and the second electrode 110 functions as an anode and the other functions as a cathode. In the present embodiment, an explanation is provided using the first electrode 106 serves as an anode which reflects visible light, and the second electrode 110 functions as a cathode which partially reflects visible light and partially transmits (semitransparent semi-reflecting cathode) as an example. In this case, it is possible to form the first electrode 106 using a highly reflective metal such as silver or aluminum or an alloy thereof. Alternatively, a conductive oxide film with translucency may be formed above a film which includes these metals or alloys. Examples of the conductive oxide include indium-tin oxide (ITO) and indium-zinc oxide (IZO). A metal thin film including a metal such as aluminum, magnesium, silver or the like or an alloy thereof and having a thickness which allows visible light to pass through can be used as the second electrode 110. Alternatively, a conductive oxide having translucency such as ITO or IZO may also be used. When the metal thin film described above is used as the second electrode 110, a conductive oxide having translucency may be stacked above the metal thin film.

A partition wall 112 which is an insulating film is arranged between the first electrodes 106 of adjacent sub-pixels 102. FIG. 2 shows the first electrode 106 and the partition wall 112, the first electrode 106 is exposed in the opening part 113 of the partition wall 112, and an end part of the first electrode 106 is covered by the partition wall 112. In this way, a step caused by the end part of the first electrode 106 is relieved, and it is possible to prevent the EL layer 108 and the second electrode 110 formed above from being cut. An organic insulating material such as epoxy resin, acrylic resin, polyimide or the like can be used as the partition wall 112.

The EL layer 108 contacts the first electrode 106 and the partition wall 112 and is arranged to cover them (FIG. 1A). The second electrode 110 is arranged so as to contact the EL layer 108. Furthermore, the EL layer 108 indicates a layer sandwiched by the first electrode 106 and the second electrode 110.

The structure of the EL layer 108 can be determined arbitrarily. In the display device 100 shown in FIG. 1A, the EL layer 108 has a hole injection layer 114, a hole transport layer 116, a light emitting layer 118, an electron transport layer 120 and an electron injection layer 122. The EL layer 108 does not necessarily have to include all these five layers, and one layer may have two functions for example. Each layer may have a single layer structure or may be formed by stacking different materials.

The hole injection layer 114 has a function for promoting hole injection from the first electrode 106 to the EL layer 108. The hole injection layer 114 can be arranged to be in contact with the first electrode 106 and the partition wall 112. It is possible to use a compound which is easily injected with holes, that is, a compound which is easily oxidized (electron donating compound) for the hole injection layer 114. In other words, it is possible to use a compound whose level of the highest occupied molecular orbital (HOMO) is shallow. For example, it is possible to use aromatic amines such as benzidine derivatives and triarylamine, carbazole derivatives, thiophene derivatives, and phthalocyanine derivatives such as copper phthalocyanine and the like. Alternatively, it is possible to use polymer materials such as polythiophene, polyaniline and derivatives thereof, and examples include poly (ethylenedioxythiophene)/poly (styrenesulfonic acid) and the like. A mixture of an electron donating compound such as the aromatic amine or carbazole derivative described above, or an aromatic hydrocarbon or the like, and an electron acceptor may also be used. A transition metal oxide such as vanadium oxide and molybdenum oxide, a nitrogen-containing heteroaromatic compound, and an aromatic compound having a strong electron-withdrawing group such as a cyano group are examples of the electron acceptor.

The hole transport layer 116 has a function for transporting holes injected into the hole injection layer 114 to the light emitting layer 118 and it is possible to use the same or a similar material to the material which can be used for the hole injection layer 114. For example, although a material having a deep HOMO level compared with the hole injection layer 114 can be used, it is possible to use a material with a difference of about 0.5 eV or less. Typically, it is possible to use aromatic amines such as benzidine derivatives.

The light emitting layer 118 may also be formed using a single compound or may have a so-called host-doped structure. In the case of the host-doped type structure, a condensed aromatic compound such as a stilbene derivative and an anthracene derivative, a carbazole derivative, a metal complex containing a ligand having benzoquinolinol as a basic skeleton, an aromatic amine, and a nitrogen-containing heteroaromatic compound such as a phenanthroline derivative and the like can be exemplified as the host material. The dopant functions as a light emitting material, and a phosphor material such as a coumarin derivative, a pyran derivative, a quinocridone derivative, a tetracene derivative, a pyrene derivative and an anthracene derivative, or a phosphorescent material such as an iridium based ortho metal complex can be used. When the light emitting layer 118 is formed using a single compound, the host materials described above can be used as a light emitting material.

As is shown in FIG. 1A, it is possible to provide the light emitting layer 118 with a different structure or different light emitting materials between adjacent sub-pixels 102. In this way, different light emission colors can be generated between adjacent sub-pixels 102. In the display device 100, it is possible to form the light emitting layer 118 so that the light emission wavelength of the light emitting material contained in the light emitting layer 118g of the second light emitting element 104g is shorter than that of the light emitting layer 118r of the third light emitting element 104r, and longer than that of the light emitting layer 118b of the first light emitting element 104b.

The electron transport layer 120 has a function for transporting electrons injected from the second electrode 110 via the electron injection layer 122 to the light emitting layer 118. A compound that is easily reduced (electron accepting) can be used for the electron transport layer 120. In other words, a compound whose level of the lowest unoccupied molecular orbital (LUMO) is shallow can be used. For example, a metal complex containing a ligand having a benzoquinolinol such as tris (8-quinolinolato) aluminum, tris (4-methyl-8-quinolinolato) aluminum as a basic skeleton, and a metal complex containing a ligand having oxadiazole or thiazole as a basic skeleton can be exemplified. In addition to these metal complexes, it is also possible to use compounds having an electron-deficient type heteroaromatic ring such as an oxadiazole derivative, a thiazole derivative, a triazole derivative or a phenanthroline derivative and the like.

A compound which promotes electron injection from the second electrode 110 to the electron transport layer 120 can be used for the electron injection layer 122. For example, it is possible to use a mixture of a compound which can be used for the electron transport layer 120 and an electron donor such as lithium or magnesium. Alternatively, an inorganic compound such as lithium fluoride or calcium fluoride may also be used.

In the present specification, a region from the top surface of the first electrode 106 to the bottom surface of the light emitting layer 118 is defined as a hole transport region, and a region from the top surface of the light emitting layer 118 to the bottom surface of the second electrode 110 is defined as an electron transport region. It is possible to include a hole injection layer 114 and a hole transport layer 116 in the hole transport region. On the other hand, it is possible to include an electron transport layer 120 and an electron injection layer 122 in the electron transport region. Therefore, the EL layer 108 is formed from a hole transport region, a light emitting layer 118 and an electron transport region. However, in the case when a layer other than the light emitting layer 118 (for example, the hole transport layer 116 or the electron transport layer 120) functions as the light emitting layer 118, the EL layer 108 is formed form a hole transport region and an electron transport region.

By providing a potential difference between the first electrode 106 and the second electrode 110, holes are injected from the former and electrons are injected into the EL layer 108 from the latter. The holes are transported to the light emitting layer 118 via the hole injection layer 114 and the hole transport layer 116. On the other hand, electrons are transported to the light emitting layer 118 via the electron injection layer 122 and the electron transport layer 120. Holes and electrons are recombined in the light emitting layer 118, and an excited state of the light emitting material included in the light emitting layer 118 is formed. When the excited state relaxes to a ground state, light which has a wavelength corresponding to the energy difference between the excited state and the ground state is emitted which can be observed as light emission from each light emitting element 104.

It is possible to form each layer included in the EL layer 108 by applying a wet film formation method such as an ink jet method, a spin coating method, a printing method and a dip coating method, or a dry film formation method such as an evaporation method. In addition to the layers described above, the EL layer 108 may also have, for example, a hole blocking layer, an electron blocking layer or an exciton blocking layer and the like.

### 1-2. Resonance Structure

It is possible to further arrange a resonance structure on the second electrode 110 in the display device 100. The resonance structure can be formed by a plurality of cap layers (first cap layer 130, second cap layer 132, third cap layer 134) as is shown in FIG. 1A.

The first cap layer 130 and the second cap layer 132 have mutually different optical distances and are arranged on the first light emitting element 104b, the second light emitting element 104g, and the third light emitting element 104r respectively. In other words, the first cap layer 130 and the second cap layer 132 are arranged side by side on the second electrode 110 opposite to the light emitter 118 of the each of the first sub-pixel 102b, the second sub-pixel 102g, and the third sub-pixel 102r respectively. That is, the first cap layer 130 and the second cap layer 132 are arranged so that one overlaps a region A which is a part of a region of the second electrode 110, and the other is arranged so as to overlap a region B which is a region excluding the region A in the region of the second electrode 110. The first cap layer 130 and the second cap layer 132 can be arranged so as to be adjacent to each other on the second electrode 110 opposite to the light emitter 118. It is preferred that the entire surface of the second electrode 110 opposite to the light emitter 118 is covered by the first cap layer 130 and the second cap layer 132. In other words, it is preferred that the surface of the second electrode 110 opposite to the light emitting layer 118 does not include regions which are exposed from the first cap layer 130 and the second cap layer 132. In a preferred embodiment of the present embodiment, the boundary between the first cap layer 130 and the second cap layer 132 can be determined by the difference in optical distance due to the thickness and refractive index thereof. Furthermore, the first cap layer 130 and the second cap layer 132 do not have to be arranged on all of the first light emitting element 104b, the second light emitting element 104g and the third light emitting element 104r, but may be arranged on at least one of the first light emitting element 104b, the second light emitting element 104g and the third light emitting element 104r.

As is shown in FIG. 1A, the first cap layer 130 and the second cap layer 132 can have different thicknesses or materials with different refractive indices within the sub-pixel 102. In this way, it is possible to provide a path having a different optical distance to the light emitted from the light emitting element 104 included in the sub-pixel 102 and emitted to the exterior of the sub-pixel 102.

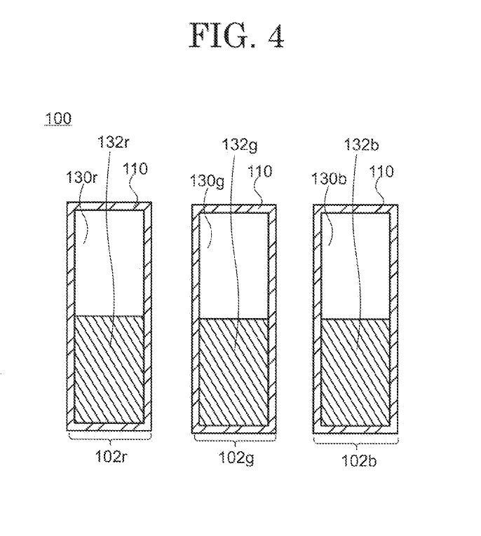

FIG. 4 is a schematic top surface diagram showing an example of an arrangement of the first cap layer 130 and the second cap layer 132 on the second electrode 110 of the display device 100 of the first embodiment. As is shown in FIG. 4, the first cap layer 130 and the second cap layer 132 may have an equal area on the second electrode 110, and in particular, the first cap layer 130 and the second cap layer 132 may be respectively positioned in a first region and a second region which separate the second electrode 110 by a line segment intersecting the long side of the second electrode 110. Furthermore, the line segment which intersects the long side of the second electrode 110 may also be orthogonal to the long side of the second electrode 110.

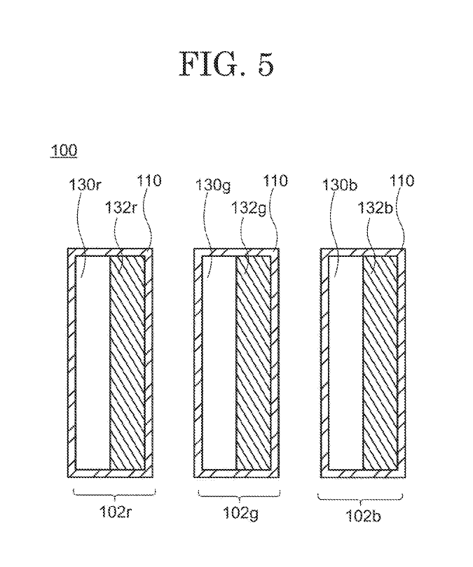

FIG. 5 is also a schematic top surface diagram showing an example of an arrangement of the first cap layer 130 and the second cap layer 132 on the second electrode 110 of the display device 100 of the first embodiment. As is shown in FIG. 5, the first cap layer 130 and the second cap layer 132 may have an equal area, and the first cap layer 130 and the second cap layer 132 may be respectively positioned in a first region and a second region which separate the second electrode 110 by a line segment intersecting the short side of the second electrode 110. Furthermore, the line segment which intersects the short side of the second electrode 110 may also be orthogonal to the short side of the second electrode 110.

In addition, although not shown in the diagram, the area of the first cap layer 130 and the area of the second cap layer 132 may be different, or one or both of them may include a plurality of cap layers. In the case where one or both of the first cap layer 130 and the second cap layer 132 includes a plurality of cap layers, the first cap layer 130 and the second cap layer 132 may have a common cap layer. In addition, both the first cap layer 130 and the second cap layer 132 may be also be included in a single cap layer structure. In this case, for example, the single cap layer structure has two regions with different thicknesses, the structure of a region where the thickness is thin in the single cap layer structure may be the first cap layer 130, and the structure of a region whether the thickness is thick may be the second cap layer 132.

As is shown in FIG. 1A, a first cap layer 130b of the first sub-pixel 102b, a first cap layer 130g of the second sub-pixel 102g, and a first cap layer 130r of the third sub-pixel 102r may have mutually different structures or different materials, and may have the same structure or the same material. Similarly, a second cap layer 132b of the first sub-pixel 102b, a second cap layer 132g of the second sub-pixel 102g and a second cap layer 132r of the third sub-pixel 102r may have different structures or different materials, and may have the same structure or the same material.

The third cap layer 134 is arranged on the first cap layer 130 and the second cap layer 132 of each of the first sub-pixel 102b, the second sub-pixel 102g and the third sub-pixel 102r respectively to overlap a first light emitting element 104b, a second light emitting element 104g and a third light emitting element 104r. Therefore, the third cap layer 134 is shared by the first sub-pixel 102b, the second sub-pixel 102g and the third sub-pixel 102r, and extends from the first sub-pixel 102b to the third sub-pixel 102r via the second sub-pixel 102g. It is possible for the third cap layer 134 to contact the first cap layer 130b and the second cap layer 132b in the first sub-pixel 102b, contact the first cap layer 130g and the second cap layer 132g in the second sub-pixel 102g, and contact the first cap layer 130r and the second cap layer 132r in the third sub-pixel 102r.

The first cap layer 130, the second cap layer 132 and the third cap layer 134 may include a material having high transmittance in the visible light band. An organic compound is exemplified as a material which has a high transmittance in the visible light band and a relatively high refractive index. The organic compound may also be a hole transporting material or an electron transporting material. A polymer material is a typical example of the organic compound and examples thereof include polymer materials containing sulfur, halogen and phosphorus. A polymer having a substituent such as thioether, sulfone, thiophene or the like in the main chain or side chain is an example of a polymer containing sulfur. A polymer material containing a phosphite group or a phosphoric acid group or the like in the main chain or side chain, or polyphosphazen and the like are examples of a polymer material containing phosphorus. A polymer material containing bromine, iodine or chlorine as a substituent is an example of a polymer material containing halogen. The polymer materials described above may be crosslinked between molecules or within molecules.

Other examples of materials which have a high transmittance in the visible light band and a relatively high refractive index include inorganic materials such as titanium oxide, zirconium oxide, chromium oxide, aluminum oxide, indium oxide, ITO, IZO, lead sulfide, zinc sulfide and silicon nitride and the like. A mixture of these inorganic materials and polymer materials may also be used.

In addition, for example, a polymer material containing fluorine is an example of a material which has a high transmittance in the visible light band and a relatively low refractive index. Examples of a fluorine-containing polymeric material include polytetrafluoroethylene, polyvinylidene fluoride, derivatives thereof, polyvinyl ether or polyimide having fluorine in the main chain or side chain, polymethacrylic acid ester, polyacrylic acid ester and polysiloxane and the like. These polymers may be crosslinked within molecules or between molecules.

Examples of inorganic materials which have a high transmittance in the visible light band and have a low refractive index include metal fluorides such as lithium fluoride, magnesium fluoride, calcium fluoride, or silicon oxide containing boron oxide and phosphorus oxide and the like.

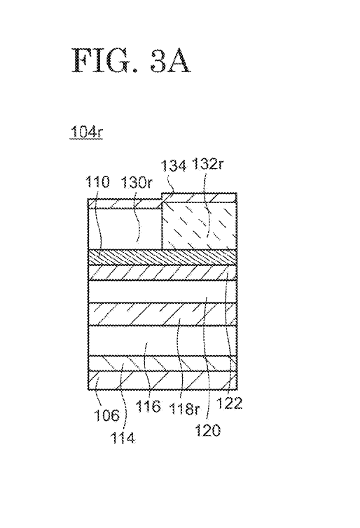

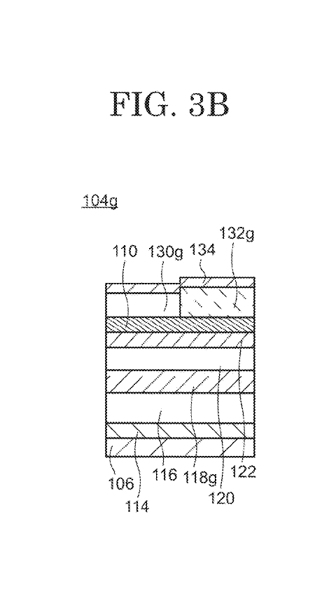

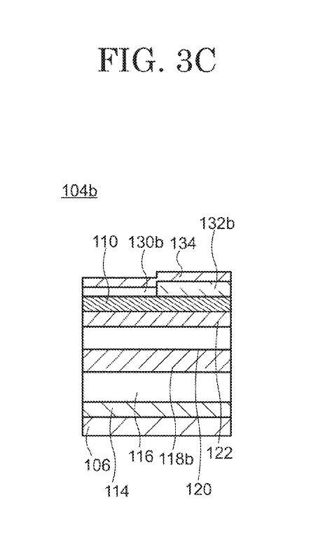

FIG. 3A, FIG. 3B and FIG. 3C show detailed structures of the third light emitting element 104r, the second light emitting element 104g and the first light emitting element 104b respectively. On the first light emitting element 104b, a stack of the first cap layer 130b and the third cap layer 134 on the first light emitting element 104b and a stack of the second cap layer 132b and the third cap layer 134 on the first light emitting element 104b are arranged as a resonant structure. On the second light emitting element 104g, a stack of the first cap layer 130g and the third cap layer 134 on the second light emitting element 104g and a stack of the second cap layer 132g and the third cap layer 134 on the second light emitting element 104g are arranged as a resonant structure. On the third light emitting element 104r, a stack of the first cap layer 130r and the third cap layer 134 on the third light emitting element 104r and a stack of the second cap layer 132r and the third cap layer 134 on the third light emitting element 104r are arranged as a resonant structure. Here, the thicknesses of the first cap layer 130b on the first light emitting element 104b, the second cap layer 132b on the first light emitting element 104b, the first cap layer 130g on the second light emitting element 104g, the second cap layer 132g on the second light emitting element 104g, the first cap layer 130r on the third light emitting element 104r, and the second cap layer 132r on the third light emitting element 104r are each CP1b, CP2b, CP1g, CP2g, CP1r and CP2r respectively.

### 1-3. Resonance

The first cap layer, the second cap layer, and the third cap layer arranged on each light emitting element 104 function as a resonance structure for resonating light which is extracted from the light emitting element 104 through the second electrode 110. One of the resonance structures of the first light emitting element 104b is the first cap layer 130b having a thickness CP1b and the third cap layer 134 having a thickness CP3, and the other is the second cap layer 132b having a thickness CP2b and the third cap layer 134 having the thickness CP3. The light which is obtained from the light emitting layer 118b passes through the second electrode 110 and enters the first cap layer 130b or the second cap layer 132b directly of after resonating within the first light emitting element 104b (that is, between the top surface of the first electrode 106 and the bottom surface of the second electrode 110). The light which enters the first cap layer 130b resonates within the first cap layer 130b and the third cap layer 134 and the light which enters the second cap layer 132b resonates within the second cap layer 132b and the third cap layer 134.

At this time, among the light which enters the first cap layer 130b, light which has a wavelength matching the optical distance of the resonance structure (first resonance structure) including the first cap layer 130b and the third cap layer 134 is amplified by an interference effect caused by repeating the reflection between the bottom surface of the first cap layer 130b and the top surface of the third cap layer 134, while light which has a wavelength which does not match the optical distance is attenuated. Similarly, among the light which enters the second cap layer 132b, light which has a wavelength matching the optical distance of the resonance structure (second resonance structure) including the second cap layer 132b and the third cap layer 134 is amplified by an interference effect caused by repeating the reflection between the bottom surface of the second cap layer 130b and the top surface of the third cap layer 134, while light which has a wavelength which does not match the optical distance is attenuated.

In the case where the wavelength of the light which is extracted from the first light emitting element 104b is λ_{b} and this light enters the first cap layer 130b, resonates in the first resonance structure and exits in a front surface direction of the first sub-pixel 102b, in the case when an odd multiple of ¼ of λ_{b} (λ_{b}/4) matches or is close to the optical distance of the first resonance structure, the light which has this wavelength λ_{b} matches the optical distance of the first resonance structure and the light of the wavelength λ_{b} is amplified. Reversely, in the case when an integer multiple of a half of λ_{b} (λ_{b}/2) (that is, a half wavelength) matches or is close to the optical distance of the first resonance structure, this light does not match the optical distance and attenuates. Therefore, by optimizing the thicknesses and materials of the first cap layer 130b and the third cap layer 134 so that the optical distance of the first resonance structure is an odd multiple of λ_{b}/4, the half width value of light which is emitted in the front surface direction of the first sub-pixel 102b becomes smaller, color purity is improved and luminosity is increased. Furthermore, the optical distance of the first resonance structure in the case where the light emitted in the front direction of the first sub-pixel 102b is considered is represented by the product of layer thickness and the refractive index of the layer, specifically, the product of the sum of the refractive index and the thickness CP1 of the first cap layer 130b and the product of the sum of the refractive index and the thickness CP3 of the third cap layer 134. The optical distance of the first resonance structure of the light emitted in an oblique direction by the angle θ with respect to the front direction of the first sub-pixel 102b increases by the optical path length of the light which passes through the first cap layer 130b and the third cap layer 134 by the layer thickness of each cap layer/cos θ.

In addition, since the second cap layer 132b has an optical distance different from that of the first cap layer 130b, the optical distance of the light which is emitted in an oblique direction by an angle θ with respect to the front surface direction of the first sub-pixel 102b is different between the first resonance structure and the second resonance structure. Therefore, in the case where light which has the wavelength λ_{b} which is extracted from the first light emitting element 104b enters the second cap layer 132b, resonates in the second resonance structure, and exits in an oblique direction by an angle θ with respect to the front direction of the first sub-pixel 102b, in the case where an odd multiple of ¼ of λ_{b} (λ_{b}/4) matches or is close to the optical distance of the second resonance structure for light emitted in an oblique direction by an angle θ with respect to the front surface direction of the first sub-pixel 102b, the light which has this wavelength λ_{b} and is emitted with the angle matches the optical distance of the second resonant structure, and the light with the wavelength λ_{b} is amplified. Reversely, in the case of when an integer multiple of half of λ_{b} (λ_{b}/2) (that is, a half wavelength) matches or is close to the optical distance of the second resonance structure for light emitted in an oblique direction by an angle θ with respect to the front surface direction of the first sub-pixel 102b, this light does not match the optical distance and attenuates. Therefore, by optimizing the thicknesses and materials of the second cap layer 132b and the third cap layer 134 so that the optical distance of the second resonance structure for light emitted in an oblique direction by an angle θ with respect to the front surface direction of the first sub-pixel 102b becomes an odd multiple of λ_{b}/4, the half width value of light which is emitted in the front surface direction with the angle of the sub-pixel 102b becomes smaller, color purity is improved and luminosity is increased.

In this way, by arranging in the first sub-pixel 102b side by side two resonance structures, a resonance structure for enhancing the light emitted from the light emitting layer in the front surface direction and a resonance structure for enhancing the light in a direction having a certain angle from the front surface direction, it is possible to improve wide viewing angle characteristics without significantly reducing light emission efficiency. At this time, since the electrical characteristics of the light emitting element do not change, the region where the two resonance structures are arranged can emit light evenly and the life characteristics are also the same, thereby it is possible to solve the problem whereby the light emission spectrum shape changes since it is dependent on the lighting time.

Similarly, the second light emitting element 104g also has a resonance structure comprised from the first cap layer 130g and the third cap layer 134, and a resonance structure comprised from the second cap layer 132g and the third cap layer 134. Due to this structure, it is possible to make the optical distance of the resonance structure of the second light emitting element 104g larger than that of the first light emitting element 104b. As described above, the display device 100 is formed so that the light emission wavelength of the second light emitting element 104g is longer than the light emission wavelength of the first light emitting element 104b. Therefore, by adopting the structure described above, it is possible to construct a resonance structure suitable not only for the first light emitting element 104b but also for the second light emitting element 104g. As a result, it is possible to improve wide viewing angle characteristics without significantly decreasing the light emission efficiency of the second sub-pixel 102g.

Similarly, the third light emitting element 104r also has a resonance structure comprised from the first cap layer 130r and the third cap layer 134 and a resonance structure comprised from the second cap layer 132r and the third cap layer 134. Due to this structure, it is possible to make the optical distance of the resonance structure of the third light emitting element 104r larger than that of the second light emitting element 104g. As described above, the display device 100 is formed so that the light emission wavelength of the third light emitting element 104r is longer than the light emission wavelength of the second light emitting element 104g. Therefore, by adopting the structure described above, it is possible to construct a resonance structure suitable not only for the first light emitting element 104b and the second light emitting element 104g but also for the third light emitting element 104r. As a result, it is possible to improve wide viewing angle characteristic without significantly decreasing the light emission efficiency of the third sub-pixel 102r.

As described above, in the display device 100, a resonance structure which has a different composition and thickness for each sub-pixel 102 is formed on the light emitting element 104, and as a result, it is possible to arrange an optimized resonance structure for each pixel having light emitting elements with different light emission wavelengths. In the case of constructing a resonance structure, usually a vapor deposition method is applied and a resonance structure is set for each sub-pixel 102 using a fine metal mask. Vapor deposition using a fine metal mask has disadvantages such as that alignment of a metal mask is difficult, unintended deposition of materials into a region shielded by the metal mask occurs, it is not always possible to deposit on the entire intended area because clogging of the metal mask opening occurs, and the metal mask damages a light emitting element by contact with the light emitting element which causes of light emission defects (dark spots) to occur. As a result, yield decreases as the number of times deposition using a fine metal mask increases, and reliability of the display device decreases.

On the other hand, as is shown in FIG. 1A and FIG. 3A to FIG. 3C, in the display device 100, it is possible to arrange the third cap layer 134 in common across the plurality of sub-pixels 102. By adopting this structure, it is possible to avoid the use of a fine metal mask when forming the third cap layer using a vapor deposition method. As a result, it is possible to reduce the number of times vapor deposition is performed by using a fine metal mask, and as a result, it is possible to manufacture a display device with improved reliability and with high yield. Furthermore, since it is possible to construct a resonance structure optimized for each light emitting element 104 having different light emission colors, it is possible to provide a display device with high color reproducibility and high efficiency, that is, a display device with low power consumption.

In addition, in the case when the pixel 101 includes a plurality of sub-pixels 102 corresponding to mutually different colors, it is preferred that the viewing angle characteristics do not vary among the plurality of sub-pixels 102. That is, it is desirable that the ratio of attenuation of the luminosity of the plurality of sub-pixels 102 corresponding to mutually different colors according to an increase in a viewing angle is equal among the plurality of sub-pixels. For example, in the present embodiment, it is preferred that the ratio of attenuation of the luminosity of each of the first sub-pixel 102b, the second sub-pixel 102g, and the third sub-pixel 102r according to an increase in a viewing angle is equal. In the sub-pixel 102 in the present embodiment, among the light which is extracted from the light emitting element 104 and enters the first cap layer 130, light which has a wavelength which does not match the optical distance of the first resonance structure attenuates, and similarly, among the light which enters the second cap layer 132 of the sub-pixel 102, light which has a wavelength which does not match the optical distance of the second resonance structure attenuates. In this way, the sub-pixel 102 in the present embodiment can adjust the degree of attenuation of light of a specific wavelength using the first resonance structure and the second resonance structure. Therefore, in the present embodiment, in the case when the pixel 101 has a plurality of sub-pixels 102 corresponding to mutually different colors, the ratio of attenuation of the luminosity of each of the plurality of the sub-pixels 102 according to an increase in the viewing angle can be made equal.

### 2. Second Embodiment

Unlike the first embodiment, in the present embodiment a case where each sub-pixel 102 includes a fourth cap layer 136 as a common cap layer in addition to a third cap layer 134 is explained. FIG. 1B shows a state in which each of the first sub-pixel 102b, the second sub-pixel 102g, and the third sub-pixel 102r include a fourth cap layer 136 which is common cap layer on the second electrode 110 opposite to the light emitting layer 118, the first cap layer 130 and the second cap layer 132 of each sub-pixel 102 are arranged on the fourth cap layer 136, and a third cap layer 134 is arranged on each of the first cap layer 130 and each of the second cap layer 132. An explanation of the material and structure of the fourth cap layer 136 is omitted since it is the same as the explanation of the third cap layer 134. In addition, since an explanation of the first sub-pixel 102b, the second sub-pixel 102g and the third sub-pixel 102r is the same as the explanation in the first embodiment except that the fourth cap layer 136 is included, it is omitted.

In the case where each sub-pixel 102 has a fourth cap layer 136, the respective first cap layer 130 and second cap layer 132 are arranged side by side thereupon, and a third cap layer 134 is included on the first cap layer 130 and the second cap layer 132, each sub-pixel 102 is arranged with a first resonance structure comprised from the first cap layer 130, the third cap layer 134, and the fourth cap layer 136, and a second resonance structure comprised from the second cap layer 132, the third cap layer 134, and the fourth cap layer 136.

In this way, in the case when the fourth cap layer 136 which is a cap layer common to each pixel is arranged, by optimizing the material and the thickness of the fourth cap layer 136, similar to the first embodiment, it is possible to arrange side by side two resonance structures, a resonance structure in which light emitted from a light emitting layer is enhanced in a front surface direction, and a resonance structure in for enhancing light in a direction having a certain angle from the front surface direction, in this way, it is possible to improve wide viewing angle characteristics without significantly reducing light emission efficiency. In addition, since the electrical characteristics of the EL layer do not change, it is possible to make a region where the first cap layer 130 is arranged on the second electrode 110 and a region where the second cap layer 132 is arranged over the second electrode 110 to emit light uniformly, and since the lifetime characteristics of both regions are also the same, it is possible to avoid the problem whereby the light emission spectrum shape changes since it is dependent on the lighting time. Furthermore, in the case where the pixel 101 includes a plurality of sub-pixels 102 corresponding to mutually different colors, it is possible to make the ratio of attenuation of the luminosity of each of the plurality of sub-pixels 102 according to an increase in the viewing angle equal between the plurality of sub-pixels 102.

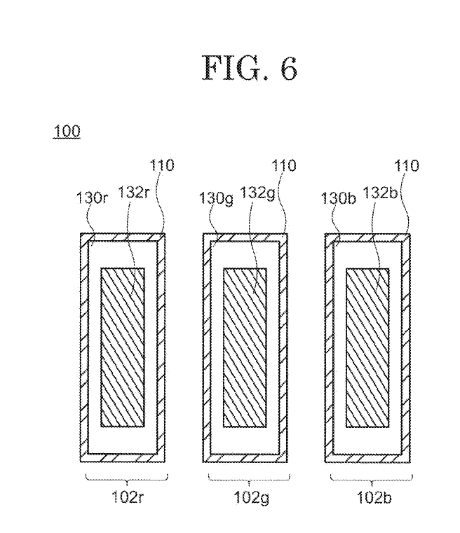

Here, although an example in which a fourth cap layer 136 which is a common cap layer, is included on the second electrode 110 opposite to the light emitting layer 118 in the first sub-pixel 102b, the second sub-pixel 102g, and the third sub-pixel 102r is shown in FIG. 6, the combinations of pixels which share the fourth cap layer 136 are not limited, and two arbitrary pixels among the pixels described above may share the fourth cap layer 136.

### 3. Third Embodiment

Unlike the first embodiment and the second embodiment, in the present embodiment, the case where the first cap layer 130 surrounds the second cap layer 132, or the second cap layer 132 surrounds the first cap layer 130 on the second electrode 110 opposite to the light emitting layer 118 is explained. FIG. 6 shows a state in which the first cap layer 130 is arranged to surround the periphery of the second cap layer 132 in each of the first sub-pixel, the second sub-pixel and the third sub-pixel. By arranging the first cap layer 130 and the second cap layer 132 in this way, it is possible to optimize the material and the thickness of the resonance structure in the sub-pixel 102, thereby it is possible to improve wide viewing angle characteristics without significantly reducing the light emission efficiency similar to the first and second embodiments. At this time, since the electrical characteristics of the light emitting element do not change, it is possible to make the region where the two resonance structures are arranged to emit light uniformly and since the life characteristics are also the same, the problem whereby the light emission spectrum shape changes since it is dependent on the lighting time can be solved. In the case where the pixel 101 includes a plurality of sub-pixels 102 corresponding to mutually different colors, the ratio of attenuation of the luminosity of each of the plurality of sub-pixels 102 according to an increase in the viewing angle can be made equal between a plurality of sub-pixels 102 corresponding to mutually different colors.

### 4. Fourth Embodiment

In the present embodiment, a method for forming the first cap layer or the second cap layer by arranging two pixels side by side is explained.

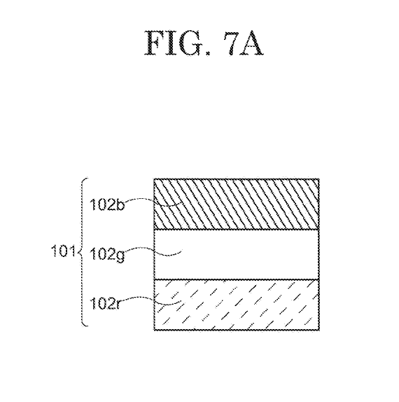

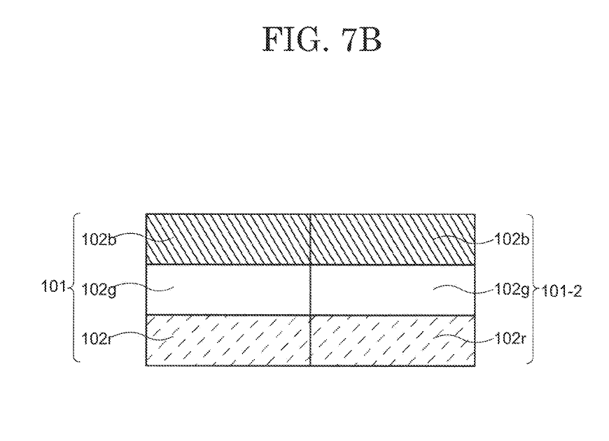

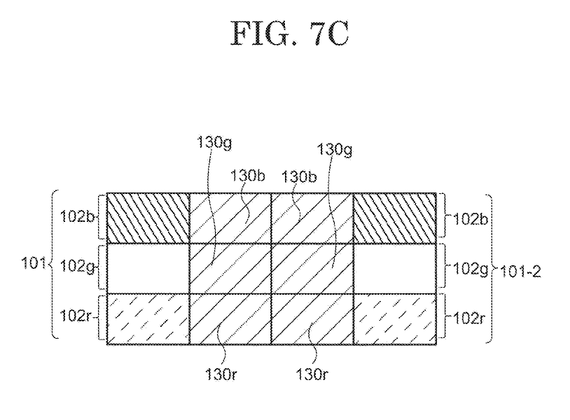

FIG. 7A is a schematic top surface diagram of a state in which the first sub-pixel 102b, the second sub-pixel 102g and the third sub-pixel 102r are arranged in a stripe shape within the pixel 101. In addition, another pixel 101-2 which has the same material and structure as the pixel 101 is prepared, and as shown in FIG. 7B, the pixel 101 and the pixel 101-2 are arranged so that pairs of the first sub-pixel 102b, second sub-pixel 102g and the third sub-pixel 102r are adjacent to each other. In addition, a mask which has a size of the pixel 101 and the pixel 101-2 is prepared, the center line of the mask is arranged so as to overlap with a segment of the pixel 101 and the pixel 101-2, and the material of the first cap layer 130 or the second cap layer 132 is deposited by vapor. FIG. 7C shows a state in which a first cap layer is formed for each pixel by vapor deposition using masks having the sizes of the pixel 101 and the pixel 101-2. By performing vapor deposition in this way, it is possible to form the first cap layer or the second cap layer using the mask having the size of the pixel 101 and the pixel 101-2, and it is possible to reduce the definition of the mask.

Each embodiment described above as embodiments of the present invention can be implemented in an appropriate combination as long as they do not contradict each other. In addition, based on the display device of each embodiment, those changes which a person skilled in the art could appropriately add, delete, or changed the design elements of, or those for which addition, omission, or a change in conditions is performed are to be included within the scope of the present invention as long as they do not depart from the gist of the present invention.

Although the case of an organic EL display device is mainly exemplified as the disclosed example in the present specification, as another application example, it is possible to use, other self-light emitting display devices, a liquid crystal display device or electronic paper type display devices including an electrophoretic display element and the like, or any flat panel type display device. In addition, the present invention can naturally be applied from medium to small size to large size applications without any particular limitations.

Even if the other actions and effects different from the actions and effects brought about by each embodiment described above are obvious from the descriptions in the present specification or those which can be easily predicted by a person skilled in the art are to be interpreted as being brought about by the present invention.

What is claimed is:

1. A display device comprising:
a pixel includes a plurality of sub-pixels;
a first cap layer having a first optical distance; and
a second cap layer having a second optical distance different from the first optical distance,
wherein
the plurality of sub-pixels each including:
a first electrode;
a second electrode facing the first electrode; and
a light emitting layer between the first electrode and the second electrode, and
the first cap layer and the second cap layer are arranged in at least one of the plurality of sub-pixels and are arranged on the second electrode.

2. The display device according to claim 1, wherein the second cap layer is arranged adjacent to the first cap layer in a plan view.

3. The display device according to claim 2, wherein the first cap layer has a first thickness and the second cap layer has a second thickness different from the first thickness.

4. The display device according to claim 2, wherein the first cap layer has a first refractive index and the second cap layer has a second refractive index different from the first refractive index.

5. The display device according to claim 2, wherein the first cap layer and the second cap layer have an equal area.

6. The display device according to claim 5,
wherein
the second electrode has a rectangular shape in plan view,
the second electrode has a first region and a second region arranged along the longitudinal direction of the second electrode,
the first cap layer is arranged on the first region,
and the second cap layer is arranged on the second region.

7. The display device according to claim 5,
wherein
the second electrode has a rectangular shape in plan view,
the second electrode has a first region and a second region arranged along the transverse direction of the second electrode,
the first cap layer is arranged on the first region,
and the second cap layer is arranged on the second region.

8. The display device according to claim 2, wherein the first cap layer and the second cap layer have different areas on the second electrode.

9. The display device according to claim 1, wherein the first cap layer surrounds the second cap layer, or the second cap layer surrounds the first cap layer.

10. The display device according to claim 1, further comprising a common cap layer,
wherein
the plurality of sub-pixels includes the common cap layer on the second electrode, and the first cap layer and the second cap layer are arranged above the common cap layer.

11. The display device according to claim 1,
wherein
the plurality of sub-pixels includes a first sub-pixel, a second sub-pixel and a third sub-pixel,
wherein
the first sub-pixel includes a first light emitting layer emitting light of a first wavelength band,
the second sub-pixel includes a second light emitting layer emitting light of a second wavelength band, and
the third sub-pixel includes a third light emitting layer emitting light of a third wavelength band,
wherein
the second sub-pixel includes the first cap layer and the second cap layer.
